(19) United States
(12) Patent Application Publication
(10) Pub. No.: US 2023/0417806 A1
(43) Pub. Date: Dec. 28, 2023

(54) CURRENT SENSING AMPLIFIER WITH OFFSET CANCELLATION

(71) Applicant: Efficient Power Conversion Corporation, El Segundo, CA (US)

(72) Inventors: Edward Lee, Fullerton, CA (US); Ravi Ananth, Laguna Niguel, CA (US); Michael Chapman, Long Beach, CA (US)

(73) Assignee: Efficient Power Conversion Corporation, El Segundo, CA (US)

(21) Appl. No.: 18/343,270

(22) Filed: Jun. 28, 2023

Related U.S. Application Data
(60) Provisional application No. 63/356,300, filed on Jun. 28, 2022.

(51) Int. Cl. G01R 19/00

(52) U.S. Cl. CPC G01R 19/0092

(57) ABSTRACT

An integrated current sensing amplifier with offset cancellation implemented in GaN technology. The current sensing amplifier senses the current flowing through a low side power FET or a high side power FET of a half bridge circuit. The current sensing amplifier uses the off time of the power FET for storing the amplifier input offset voltage. The stored amplifier input offset voltage is then used to cancel the amplifier input offset voltage during the on time of the power FET, which is the interval that requires current sensing.

This application claims the benefit of U.S. Provisional Application No. 63/356,300, filed Jun. 28, 2022, the disclosure of which is incorporated by reference in its entirety.

### BACKGROUND

Current sensing is required in many power converters for the purposes of both detecting over current conditions and for improving the voltage regulation in closed loop control. Current sensing can be achieved using different methods, such as measuring the R_{DS(on)} of the power FET, inductive coupling, using a small sensing FET in parallel with a power FET or using current sensing resistors. The use of current sensing resistors is the most common method.

When sensing resistors are used, the current sensing resistor, the current sensing resistor Rs can be placed in series with the inductor of the power converter. The current sensing resistor Rs can also be placed in series with the high-side (HS) power FET of the half-bridge that connects to the supply voltage and/or in series with the low-side (LS) power FET of the half-bridge that connects to ground, as shown in FIG. 1A.

The current sensing resistor can also be placed in series with a small sensing FET 100 to the power FET as shown in FIG. 1B. In this case, the power loss due to the current sensing resistor is minimized. However, the current sensing accuracy will be dependent on the matching between the small sensing FET 100 and the power FET 102.

If the current sensing resistor Rs is connected in series with the either the power FET (FIG. 1A) or the small sensing FET (FIG. 1), the voltage across the current sensing resistor must be minimized to reduce power dissipation, which requires that the current sensing resistor is small. Thus, a current sensing amplifier 106 is required to amplify the voltage at the current sense input Si. Since the current sensing amplifier 106 amplifies the voltage at the sensing input Si, any voltage offset at the input Si of the current sensing amplifier 106 reduces the accuracy of the current sensing, i.e., the accuracy at the output So of the current sensing amplifier 106.

FIG. 2 shows a conventional low side current sensing circuit using resistors and an op amp. The sensed voltage output from the op amp, So, is equal to Id·Rs·R2/R1+Vref. The circuit of FIG. 2 has the following disadvantages:

1. If op the amp has an input offset voltage of Vos, the output So will have an additional output offset equal to Vos·(1+R2/R1). Op amps realized in GaN technology usually have high voltage offset Vos due to high FET-threshold voltage shifts and mismatch found in GaN technologies.

2. The common mode voltage at the op amp input, V_{CMI}, is close to ground for low side current sensing. This is not suitable for an enhancement mode NFET differential input stage. As a result, the required op amp is difficult to realize in GaN technologies, since only enhancement mode GaN NFETs are currently available.

FIG. 3 shows a conventional high side current sensing circuit 300. The voltage across R1 is equal to voltage across sensing voltage Rs due to op amp feedback loop. PFET 302 is used to convey current flow on R1 to R2 that connects to ground. Due to current flow through PFET 302, the output voltage V_{O} is equal to I_{HS}·Rs·R2/R1.

The high side current sensing circuit 300 of FIG. 3 has the following disadvantages:

1. The common mode voltage at the op amp input, V_{CMI}, is approximately equal to Vin. As a result, the op amp supply voltage must be between Vin and ground. For a large Vin, the op amp will have a high amount of power dissipation. Moreover, the op amp of FIG. 3, which includes a PFET, is difficult to realize in GaN technology since only NFETs are currently available in GaN.

2. If the supply of the op amp floats with the SW node (swinging between Vin and ground), a wide op amp input common mode range will be required.

3. As in the current sensing circuit of FIG. 2, the op amp offset voltage will be amplified at the output V_{O} and this will adversely affect the accuracy of Vo.

### SUMMARY OF THE INVENTION

It would therefore be desirable to provide an amplifier with current sensing amplifier with offset cancellation in GaN technology that overcomes the disadvantages of the prior art noted above.

More specifically, the present invention takes advantage of the situation that the drive current ID flowing through the power FET need only be sensed when the power FET is on. The present invention uses the off times for storing the amplifier input offsets on capacitors. The stored offsets are then used for cancelling the amplifier input offsets during the power FET on times, which is the interval that requires current sensing.

The amplifier offset cancellation technique of the present invention is used for sensing both the low side and high side current in a half bridge power converter. For high side current sensing, an off-chip PFET can be used to convey the sensed current to a ground referenced resistor. Alternatively and preferably, to allow current sensing amplifier to be fully integrated in GaN (where PFETs are not yet available), the off-chip PFET is replaced with a GaN FET, and the control voltage applied to the gate of the GaN FET is level shifted down to close to ground.

Additional features and advantages of the invention will be set forth in the description which follows, and in part will be obvious from the description, or may be learned by the practice of the invention. The features and advantages of the invention may be realized and obtained by means of the instruments and combinations particularly pointed out in the appended claims. These and other features of the present invention will become more fully apparent from the following description and appended claims, or may be learned by the practice of the invention as set forth hereinafter.

### BRIEF DESCRIPTION OF THE DRAWINGS

The advantages and features of the present invention will become apparent when the following description of the preferred embodiments of the invention is read in conjunction with the accompanying drawings, in which:

FIG. 1A shows a conventional low side current sensing circuit with a current sensing resistor in series with the low side power FET.

FIG. 1B shows a conventional low side current sensing circuit with a current sensing resistor in series with a small sensing FET.

FIG. 2 shows a conventional low side current sensing circuit using resistors and an op amp.

FIG. 3 shows a conventional high side current sensing circuit with resistors and an op amp.

FIG. 4 shows an integrated low side current sensing amplifier with offset cancellation in accordance with the present invention, FIG. 4A shows the current sensing circuit and amplifier input offset voltages, FIG. 4B shows the current sensing circuit for the integrated low side current sensing amplifier of FIG. 4A during the off (reset) time, and FIGS. 4C and 4D show the current sensing circuit for the integrated low side current sensing amplifier of FIG. 4A during the on (sensing) time without and with an input signal, respectively.

FIG. 5A shows the low side current sensing circuitry of the present invention with a capacitive reset gain circuit, and FIGS. 5B and 5C show the current sensing circuit during the reset phase and the current sensing phase, respectively.

FIG. 6 shows the high side current sensing amplifier with offset cancellation of the present invention, and FIG. 6A shows the circuitry of a Supply & clock generator used in the high side current sensing circuit.

FIG. 7 shows the high side current sensing amplifier using an off-chip P-MOSFET, and FIGS. 7A and 7B show the current sensing circuit during the reset phase and the current sensing phase, respectively.

FIG. 8 shows the high side current sensing amplifier without using a P-MOSFET, FIG. 8A shows the circuitry of an Off-state SO and VB generator used in the circuit, and FIGS. 8B and 8C show the current sensing circuit during the reset phase and the current sensing phase, respectively.

FIG. 9 shows an integrated high side current sensing amplifier with a sensing FET.

FIG. 10 shows the high side current sense amplifier circuitry for the integrated circuit of FIG. 9, and FIGS. 10A and 10B show the current sensing circuit during the reset phase and the current sensing phase, respectively.

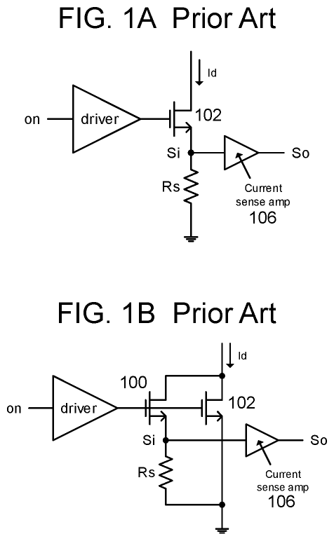

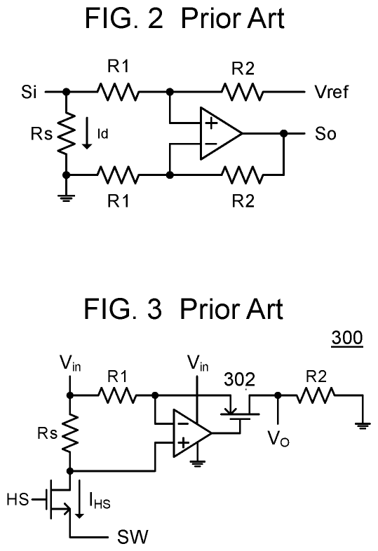

### DETAILED DESCRIPTION OF THE PREFERRED EMBODIMENTS

It is to be understood that the figures and descriptions of the present invention may have been simplified to illustrate only elements that are relevant for a clear understanding of the present embodiments. Those of ordinary skill in the art will recognize that other elements may be desirable and/or required in order to implement the present embodiments. It is also to be understood that the drawings included herewith only provide diagrammatic representations of the presently preferred embodiments of the present invention. Reference will now be made to the drawings wherein like structures are provided with like reference designations.

Low Side Current Sensing Architecture

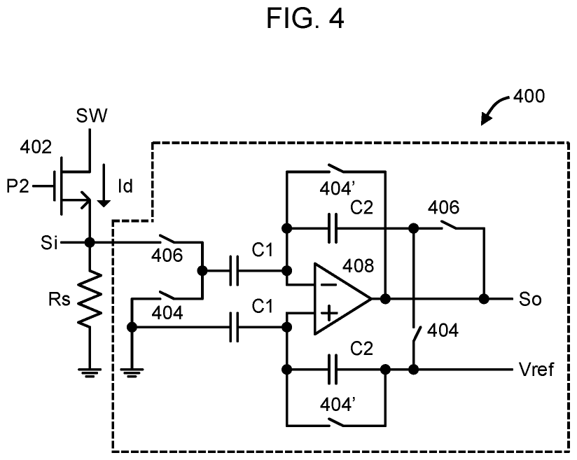

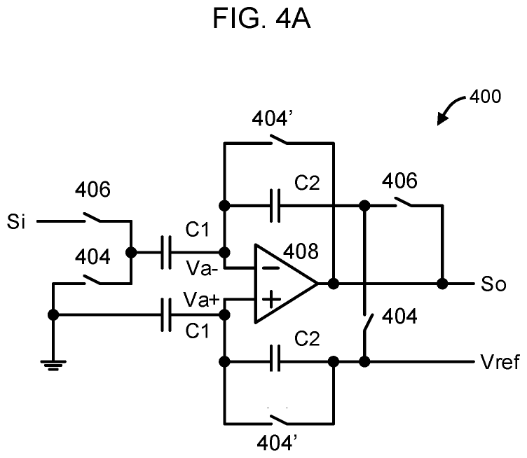

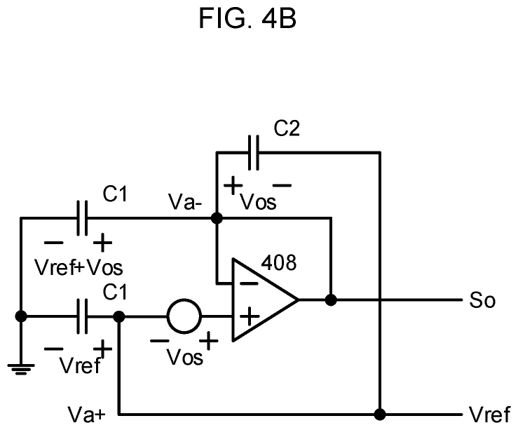

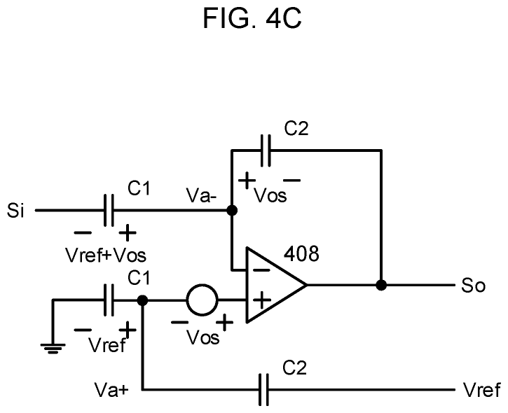

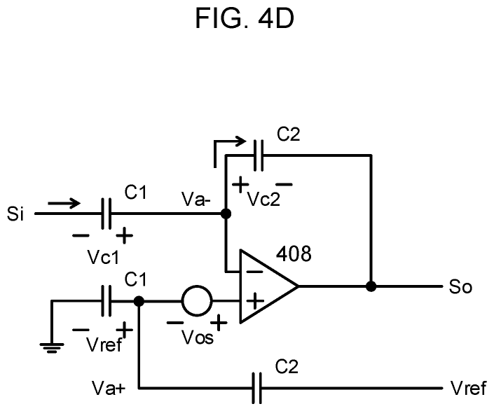

FIG. 4A is a circuit schematic of the integrated low side current sensing amplifier with offset cancellation of the present invention, identified generally by reference number 400. The current sensing amplifier is provided with an op amp circuit which senses the current flowing through a low side power FET 402 at the Si node. The current is sensed with an op amp circuit including an op amp 408 and two input branches from the Si node, each including a capacitor C1. The input capacitor C1 of the lower branch is connected at one side to the non-inverting input of the op amp, and at the opposite side to ground. The input capacitor C1 of the upper branch is connected to the inverting input of op amp 408 and is alternatively connected to ground by switch 404, or to the sensing input Si by switch 406. Switches 404, 404′ and 406, preferably implemented as GaN FET transistors, are driven by the on and off timing signals for the switching of low side power FET 402.

A fundamental principle underlying the present invention is that, since current sensing in the invention is integrated with the gate driver that drives low side power FET 402, the on and off timing signals for power FET 402 can be used in controlling the switches 404, 404′ and 406 of the current sensing amplifier. When power FET 402 is off, current sensing on the power FET is unnecessary. Therefore, in accordance with the present invention, this off time interval is utilized for resetting the current sensing amplifier to achieve offset cancellation. The utilization of the off time interval for this purpose is a fundamental feature of the invention.

More specifically, in the operation of the low side current sensing circuit 400, when low side power FET 402 is off, switch 404 is closed, and the amplifier is in reset phase and stores the op amp offset on the C1 and C2 capacitors. When low side power FET 402 is on, switch 406 is closed, and current sensing is performed. This is the amplifying phase, with the op amp offset canceled by the offset stored on the on the C1 and C2 capacitors. The op amp output So is equal to −C1/C2·Si+Vref.

The operation of the low side current sensing amplifier of FIG. 4A is now explained with reference to FIGS. 4B-4D, which show the electrical connections of the components of low side sensing circuit 400 with the switches opened/closed in the two operating states (i.e., current sensing off or on).

In FIGS. 4B-4D, op amp 408 is modeled as an ideal op amp with an offset voltage Vos at the positive op amp input terminal.

Referring first to FIG. 4B, the reset phase, when switches 404 and 404′ are on and switches 406 are off (no current sensing), op amp 408 is in unity gain feedback. Therefore Va+=Vref and Va−=Vref+Vos, where Va+ is the voltage at the positive input of op amp 408 and Va− is the voltage at the negative input of op amp 408. The input offset voltage Vos of amp 408 is stored on the capacitors C1 and C2 and the output voltage at So is equal to Vref+Vos. This output value—when switch 404 is on—is not important, since the sense amplifier does not need to sense the current during this time interval.

When switches 406 are on, and switches 404 and 404′ are off (FIG. 4C), current sensing occurs, and sense amplifier 408 must provide the correct output value. (Switch 404′ is timed to turn off slightly before switch 404 to reduce the effects of clock feedthrough/charge injections when switches 404 and 404′ are opened).

If the input Si is at ground (0V) during the current sensing phase, the voltages across the capacitors C1 and C2 remain the same as the voltages in circuit connection of FIG. 4B. The output voltage at So is equal to Va− minus the voltage across the top of capacitor C2, that is equal to (Vref+Vos)−Vos=Vref, which is the desired value for Si=0V (no current).

Referring to FIG. 4D, under the same switch conditions as FIG. 4C (switches 406 are on, switches 404 and 404′ are off), if Si is non-zero, current is flowing, and the charge stored on the upper capacitor C1 is changed by the amount of Si×C1, with charge flowing into the top capacitor C1 and the top capacitor C2, as indicated by the arrows. The same amount of charge changed on capacitor C1 is transferred to C2, with the voltage change on Vc2 given as (Si×C1)/C2. Note that the initial V_{C2} value is Vos before switch 406 turns on.

Since So=Va−−Vc2, So=(Vref+Vos)−(Vos+(Si×C1)/C2)=Vref−(Si×C1)/C2

Thus, as shown above, the low side current sensing amplifier of the present invention advantageously cancels out the offset voltage Vos of the amplifier at the output So.

Note that, for a positive Si, the output So is less than Vref, and for negative Si, the output So is greater than Vref. In certain cases, it may be more desirable to have So to be greater than Vref for a positive input Si, and for So to be less than Vref for negative input Si. This can be implemented by flipping the switch arrangement and ground connection of switches 504 and 506 connected between the input Si and the input capacitors C1.

Low Side Current Sensing Architecture with Capacitive Reset Gain

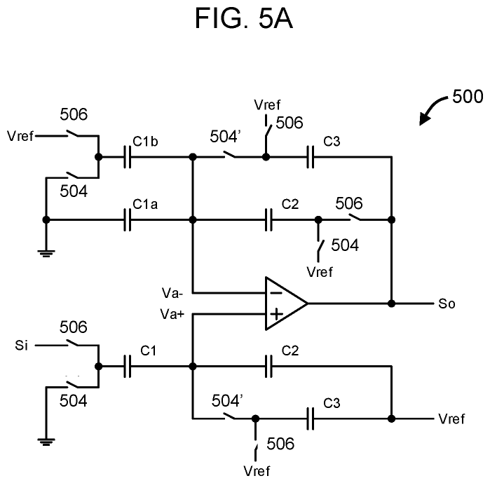

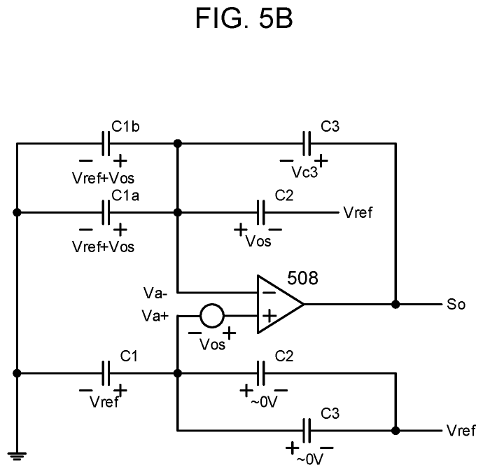

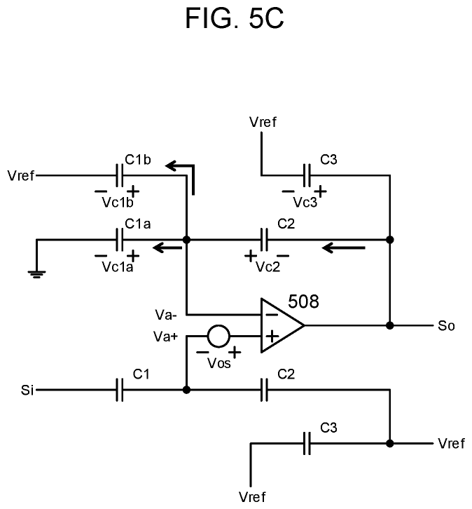

One of the drawbacks of using the offset cancellation circuit shown in FIG. 4A is that the feedback gain of the op amp during the reset phase (when switches 404 and 404 are on) is unity, which is different from the feedback gain, C2/(C1+C2), during current sensing phase when switch 406 is on. This difference in feedback gain makes the frequency compensation of the op amp complicated. To address this issue, a capacitive reset gain circuit is provided in a second embodiment of the low side current sensing amplifier of the present invention, as depicted in FIG. 5A and identified generally by reference number 500. By using capacitive reset gain circuitry, the feedback gain for both phases remains the same and is approximately equal to C2/(C1+C2) when C2 is equal to C3. Note that C1a+C1b=C1 of FIG. 4A. C1b is used in the circuit of FIG. 5A such that, when switch 506 is closed with Si=0V, the output voltage So can be set to Vref/2 if C1b is set to half of C2.

The operation of the low side current sensing amplifier of FIG. 5A is now explained with reference to FIGS. 5B and 5C, which show the electrical connections of the components of low side sensing circuit 500, with the switches opened/closed in the two operating states (i.e., current sensing off or on).

Referring first to FIG. 5B, in the reset phase, when switches 504 and 504′ are on and switch 506 is off (no current sensing), the bottom C3 and its associated switches (FIG. 5A) form an equivalent (switched-capacitor) resistor. So, after a number of clock cycles, the bottom C1 will be charged to Vref and hence Va+ is equal to Vref in steady state.

Op amp 508 can be modeled as an ideal op amp with an input offset voltage of Vos.

Due to the top C3, which closes the op amp feedback loop, Va−=Va++Vos=Vref+Vos. (Note that the term “capacitive reset” used herein comes from the fact that the reset of the op amp is achieved by using capacitor C3). As a result, the voltages across C1a and C1b are equal to Vref+Vos, and the voltage across the top C2 is equal to Vos.

The voltage stored on the top C3 is the output voltage So in the previous clock phase (switch 506 is closed) minus Vref, as is apparent from FIGS. 5C and 5D below.

The output voltage So during this clock phase (when switch 504 is on/closed) is not important since the high side power FET is assumed to be off during this clock phase and there is no need to sense the power FET current.

Turning now to FIG. 5C, when switches 506 are on, and switches 504 and 504′ are off, current sensing occurs, and sense amplifier 408 must provide the correct output value. Due to change in the input voltage on Si, Va+ will be changed. The amount of change in Va+ can be calculated based on the voltage divider formed by the bottom C1 and C2, and is given as C1/(C1+C2)×Si.

Hence, Va+=C1/(C1+C2)×Si+Vref and, due to the op amp feedback loop,

Va−=Va++Vos=C1/(C1+C2)×Si+Vref+Vos.

The voltage change on C1a=C1/(C1+C2)×Si+Vref+Vos·(Vref+Vos)=C1/(C1+C2)×Si

Voltage change on C1b=[C1/(C1+C2)×Si+Vref+Vos−Vref]−(Vref+Vos)=C1/(C1+C2)×Si−Vref

The above noted voltage changes on C1a and C1b will result in charge changes on C1a and C1b. These charge changes will be provided from the top C2 (arrows illustrate the charge flow). Therefore, the charge change on the top C2 can be written as:

C2×[(So−Va−)−(−Vos)]=C1a×[C1/(C1+C2)×Si]+C1b×[(C1/(C1+C2)×Si−Vref]

In the second current sensing phase, Va−=C1/(C1+C2)×Si+Vref+Vos and C1=C1a+C1b are substituted into the previous equation:

C2×[So−C1/(C1+C2)×Si−Vref]=C1×[C1/(C1+C2)×Si]−C1b×Vref

Hence, So=C1/C2×Si+(1−C1b/C2)×Vref

If C1b is selected to be half of C2, when Si=0V, So will be equal to half of Vref. Other values are possible by selecting different C1b and C2.

As shown above, the offset of the op amp is cancelled during the current sensing phase. The gain of the current sense amplifier of this embodiment (FIG. 5A) is given as C1/C2.

The voltage across C3, Vc3, is equal to So−Vref. (Vc3 will remain the same for the next reset phase, when switch 504 turns on).

### High Side Current Sensing Architecture

The present invention also includes a current sensing amplifier for sensing current flowing through the high side FET of a half bridge circuit.

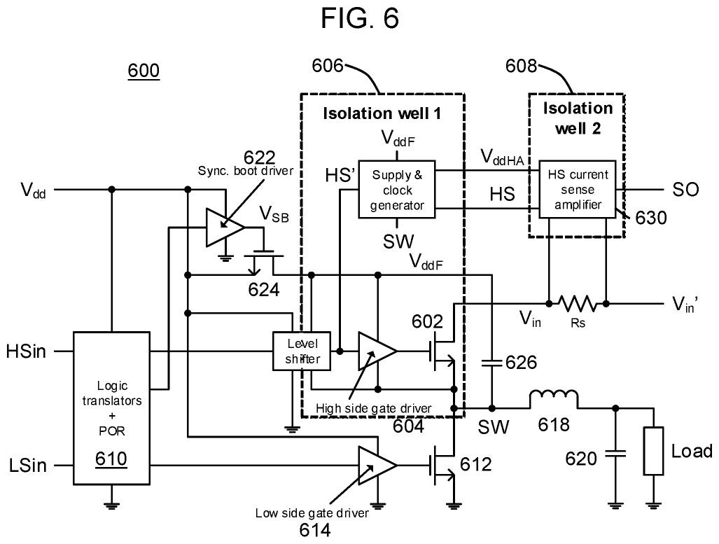

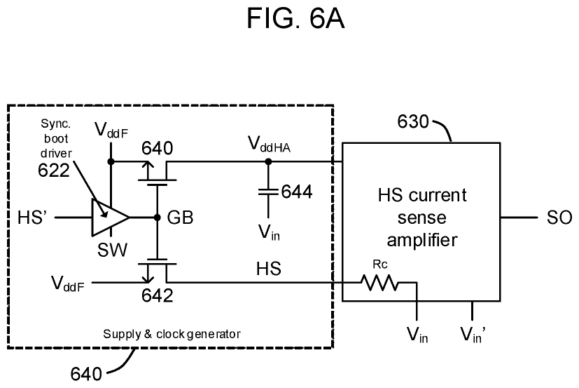

FIG. 6 shows a half bridge integrated circuit design with a synchronous bootstrap high side gate driver circuit. The half-bridge IC design 600 of FIG. 6 includes high-side power FET 602 and low-side power FET 612 which are controlled to supply switched power at the SW node to a load 616 connected to an inductor 618 and a capacitor 620 in a buck converter topology.

High-side power FET 602 is driven by a high-side gate driver 604, both which are formed within an isolation well 606. High-side gate driver 604 receives a high-side input signal from a level shifter 608, which is controlled by logic transistors and power-on reset (POR) circuitry 610, which are in turn controlled by high-side input control signal ‘HSin’ and low-side input control signal ‘LSin’. Low-side power FET 612 is driven by a low-side gate driver 614 that receives a control signal from the logic transistors and power-on reset (POR) circuitry 610 based upon the high-side signal ‘HSin’ and low-side signal ‘LSin’. The synchronous bootstrap circuit includes a synchronous bootstrap driver 622 and a synchronous bootstrap FET 624, which charges a synchronous bootstrap capacitor 626.

The current flowing through the high side power FET 602 is sensed through the voltage across sense resistor Rs when the high side power FET 602 is on with HS' being logic high. When high side power FET 602 is off when HS' is logic low, current sensing on Rs is not required.

As shown in FIG. 6, the high side current sense amplifier 630 is realized in a separate isolation well 608 (well 2), which is different from the isolation well 606 (well 1) that is used for other high side circuitry, as described above. The supply voltage for the high side current sense amplifier 630 is between VddHA and Vin.

The Supply & clock generator 640 inside the first isolation well 606 is used to provide the supply voltage (VddHA) with respect to Vin and a clock signal HS to the high side current sense amplifier 630. The circuitry of Supply & clock generator 640 is shown in detail in FIG. 6A, and includes, in addition to synchronous bootstrap driver 622, a pair of additional synchronous bootstrap FETs 640 and 642, and an additional bootstrap capacitor 644.

The operation of the high side current sensing circuit is as follows. When HS' is on, synchronous bootstrap FET 624 is on, and SW is approximately equal to Vin. During this time, the output of synchronous bootstrap driver 622 inside the Supply & clock generator 640 will drive the node GB above the high side supply voltage VddF. As a result, synchronous bootstrap FETs 640 and 642 are on, such that VddHA with respect to Vin will be charged to approximately the voltage between VddF and SW. (Note that VddF−SW is approximately equal to Vdd). The high side clock signal HS, which swings between VddHA and Vin, is generated and is synchronous to HS′.

Two different ways to realize the high side current sense amplifier 630 are possible.

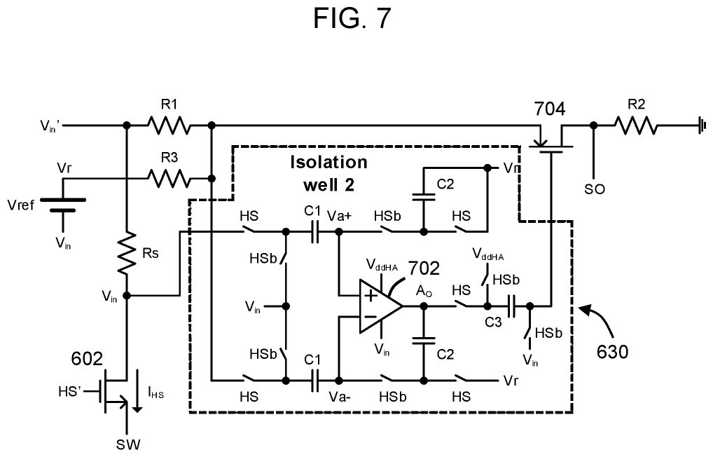

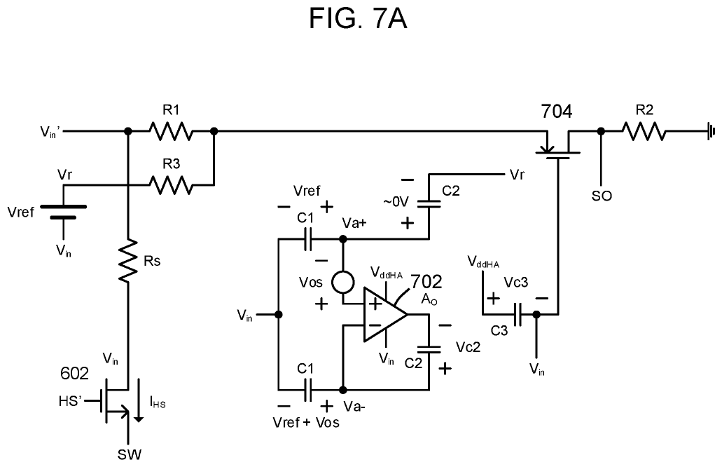

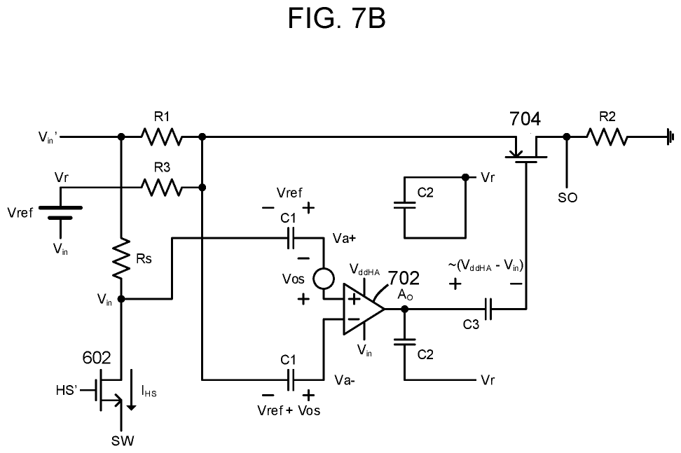

FIG. 7 shows the first embodiment of the high side current sense amplifier of the present invention, which uses an off-chip PMOS. The PMOS is off-chip because PFETs are not available yet in GaN processes, which is the preferred technology for implementing the integrated circuit of the present invention.

In the high side current sense amplifier of FIG. 7, the reference voltage Vref (referenced to Vin), together with resistor R3 is used to provide a non-zero voltage on the current sense amplifier output SO, when high side current I_{HS} is zero, with HS' and the HS input being logic high. As a result, for a negative high side current I_{HS}, the current sense output SO can still be above ground.

Vref is also used to set the input common-mode of the op amp to be approximately equal to Vref with respect to Vin.

When the HS input is logic low, the high side power FET 602 is off and sensing I_{HS} is not required. During this time, the op amp 702 is reset, such that its offset voltage will be stored on C1. (Note that HSb is the inverted logic signal of HS).

When HS is logic high, the high side power FET 602 is on, and sensing the high side current I_{HS} is required. During this time, the op amp 702, together with all the resistors, external PMOS FET 704 and Vref is used to measure high side current I_{HS} and produce an output on SO. The op amp offset is canceled during this time.

C3 is used for level shifting the op amp output voltage A_{O} to control the gate voltage of external PFET 704, which is usually below Vin when PFET 704 is an enhancement mode GaN FET. Since the source of PFET 704 is approximately at Vin, the gate of PFET 704 must be lower than Vin for PFET 704 to be on, due to the threshold voltage of PFET 704.

The operation of high side current sensing amplifier 630 will now be described with reference to FIG. 7A (the reset phase, when the HS input is low) and FIG. 7B (the current sensing phase, when the HS input is high).

In the reset phase, shown in FIG. 7A, the top C2 behaves like a (switched-capacitor) resistor and the voltage across the top C2 is approximately equal to 0V in steady state. As a result, C2 charges Va+ to Vref with respect to Vin in steady state, such that the input common-mode voltage of op amp 702 will be approximately Vref with respect to Vin, with the voltage across the top C1 being Vref.

Due to the op amp feedback loop associated with the bottom C2 and C1, Va−=Va++Vos=Vref+Vos (w.r.t. Vin). Hence, the voltage across the bottom C1 is Vref+Vos.

The voltage stored on the bottom C2 is the op amp output voltage A_{O} in the previous current sensing phase (HS is high) minus Vr, as will be apparent from the current sensing phase shown in FIG. 7B. The use of C2 for resetting op amp 702 is for simplifying the frequency compensation of the op amp by having the op amp feedback gain to be less than 1, and equal to C2/(C1+C2). The voltage across C3, VC3, is charged to VddHA−Vin during this phase.

Since the source voltage and the voltage at the gate of FET 404 are both at approximately Vin, the source-to-gate voltage of FET 704 is less than the threshold voltage of FET 704. Hence, FET 704 is off, and the current sense output SO is 0V.

In the current sensing phase, shown in FIG. 7B, the output of op amp is connected to PFET 704 through C3, and a feedback loop is created with the op amp 702, Vref, R1 and R3. Although the output of op amp 702, A_{O}, can only swing between VddHA and Vin, the voltage stored on C3, approximately (VddHA−Vin), will allow op amp 702 to control the gate of PFET 704 to be below Vin.

The circuit now has a similar configuration to the conventional high side current sensing circuit of FIG. 3, with the addition of Vref and R3.

Due to the feedback loop, the source voltage of PFET 704 will be set equal to the power FET drain voltage (equal to Vin). Importantly, the op amp offset voltage, Vos, is canceled by the offset voltage stored on the bottom C1. Hence, the disadvantageous effects due to amplification of op amp offset are minimized. Also, the voltage across the bottom C2 is equal to A_{O}−Vr.

Due to the feedback loop, the voltage across R1 will be equal to the voltage across Rs that is equal to I_{HS}×Rs=Vin′−Vin. As a result, the current flow through R1 is equal to the high side current I_{HS}×Rs/R1.

Including the current from the voltage reference, the current flow to the source of PFET 704 is equal to I_{HS}×Rs/R1+Vref/R3 and hence, current sense output SO=(I_{HS}×Rs/R1+Vref/R3)×R2.

High Side Current Sensing Amplifier without PMOS

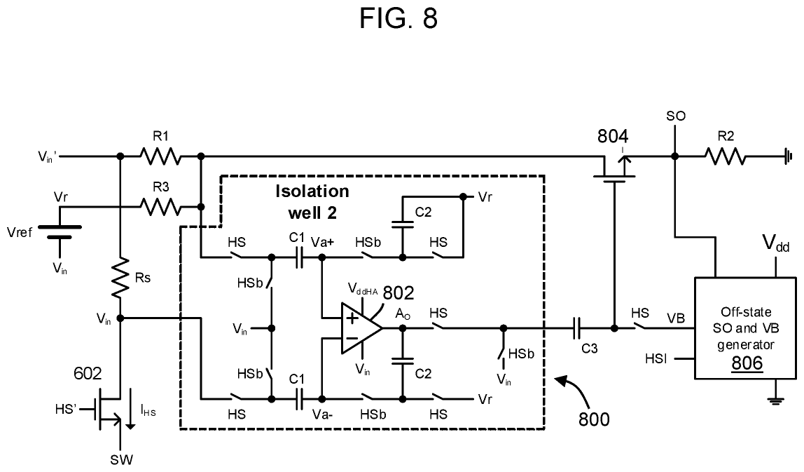

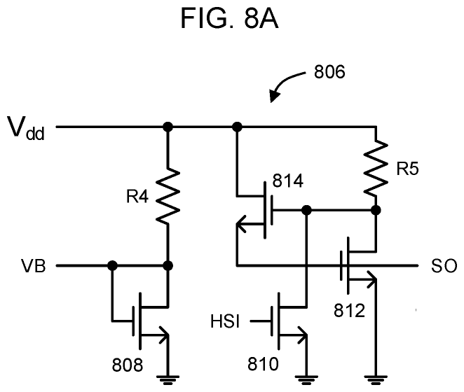

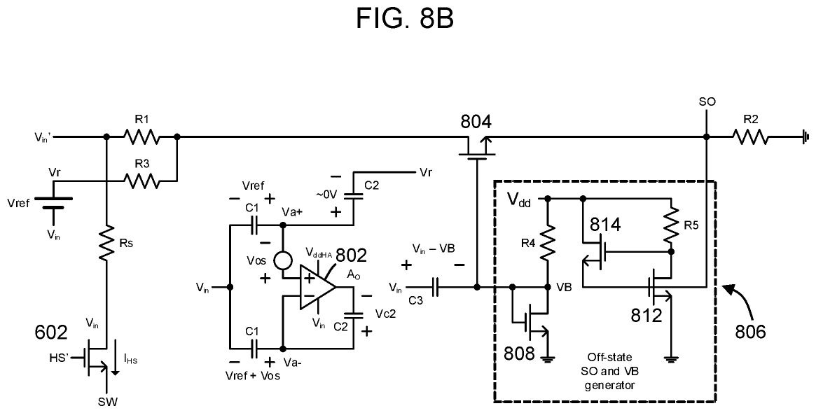

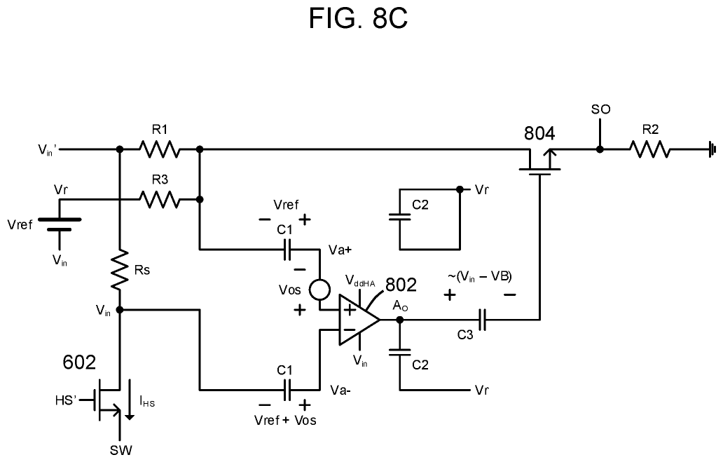

FIG. 8 shows a high side current sensing amplifier 800 in which the P-MOSFET 704 of FIG. 7 is replaced with a GaN NFET 804, so that the high side current sensing amplifier can be fully integrated in GaN technology (GaN PFETs are not yet available). However, the output of op amp 802 must control the gate of NFET 804, which is close to ground, and op amp 802 can only have an output swing between VddHa and Vin. Thus, C3 is provided for level shifting the op amp output swing to produce a control voltage for the gate of GaN FET 804 which is close to ground during the current sensing phase.

To produce a control voltage close to ground during the current sensing phase, an Off-state SO and VB generator 806, which is ground referenced, is provided. The circuitry of Off-state SO and VB generator 806 is shown in FIG. 8A. During the reset phase (FIG. 8B below), Off-state SO and VB generator 806 generates a bias voltage VB, such that the voltage across C3 is charged to Vin−VB. This voltage is used for level shifting the op amp output swing to the gate of NFET 804, such that gate voltage is equal to AO−(Vin−VB), which is close to ground.

During the reset phase, NFET 804 is off, as shown in FIG. 8B. If a non-zero current sense output SO is desired during this phase, the off-state SO and VB generator 806 is also used for providing non-zero SO.

For full integration, R1, R2 and R3 can be implemented on-chip. Matching among these resistors can be achieved.

Note that C3 is required to be a high voltage (greater than Vin) capacitor and can be realized as an integrated GaN FET by connecting the gate and the source terminals of the GaN FET to the gate of NFET 804, with the drain terminal being the other capacitor terminal.

The operation of high side current sensing amplifier 800 will now be described with reference to FIG. 8B (the reset phase, when the HS input is low) and FIG. 8C (the current sensing phase, when the HS input is high).

During the reset phase, shown in FIG. 8B. sensing the high side current I_{HS} is not required, and the op amp is reset in a similar manner as shown in FIG. 7A. The op amp offset voltage, Vos, is stored on the bottom C1, and C3 is charged between Vin and VB.

Although VB can be set to ground, VB is chosen to be one gate-to-source voltage, Vgs, above ground as determined by FET 808 in Off-state SO and VB generator 806. The advantage of doing this will become apparent in the discussion below with respect to FIG. 8C (the current sensing phase).

FET 812, FET 814 and R5 in Off-state SO and VB generator 806 will produce a voltage on SO equal to the gate-to-source voltage (Vgs) of FET 812 during this phase (reset).

Since SO is equal to the Vgs of FET 812, and the gate voltage of FET 804 (VB) is equal to the Vgs of FET 808, the Vgs of FET 804 will be very small and less than the threshold voltage of FET 804. Hence, FET 804 will be off, and SO is determined by Off-state SO and VB generator 806.

During the current sensing phase, shown in FIG. 8C, the op amp output AO controls the voltage at the gate of FET 804 through C3. As a result, a feedback loop consisting of op amp 814, Vref, FET 804, R1 and R3 is formed.

Due to the feedback loop, the drain voltage of FET 804 will be set equal to the power FET 602 drain voltage (equal to Vin). Importantly, the op amp offset voltage, Vos, is canceled by the offset voltage stored on the bottom C1. Hence, the adverse amplification of op amp offset is minimized.

Due to the feedback loop, the voltage across R1 will be equal to the voltage across Rs that is equal to I_{HS}×Rs=Vin′−Vin. As a result, the current flow through R1 is equal to I_{HS}×Rs/R1.

Including the current from the voltage reference, the current flow to the drain of FET 804 is equal to I_{HS}×Rs/R1+Vref/R3 and hence, the current sense output SO=(I_{HS}×Rs/R1+Vref/R3)×R2.

Since AO can have a swing between VddHA and Vin, including the voltage drop VgsN across C3 and the Vgs of FET 804, the current sense output SO can have a swing between VddHA−Vin+VB−VgsN and Vin−Vin+VB−VgsN. Note that VddHA−Vin is approximately equal to Vdd (paragraph [0070] above). Then SO can have a swing between Vdd+VB−VgsN and VB−VgsN. Since SO cannot swing below ground, the actual swing on SO is between Vdd+VB−VgsN and ground (that is less than Vdd for VB=0V).

By setting VB to one Vgs (approximately equal to VgsN) instead of 0V, the swing on SO becomes approximately between Vdd and ground. Hence, setting VB to one Vgs, instead of 0V, allows SO to have a swing of a full supply voltage (i.e., Vdd).

High Side Current Sensing Amplifier with Sensing FET

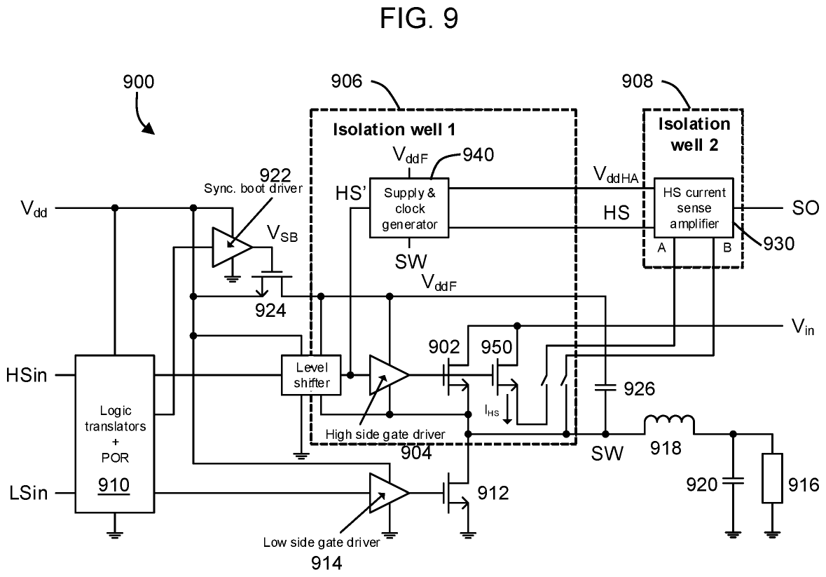

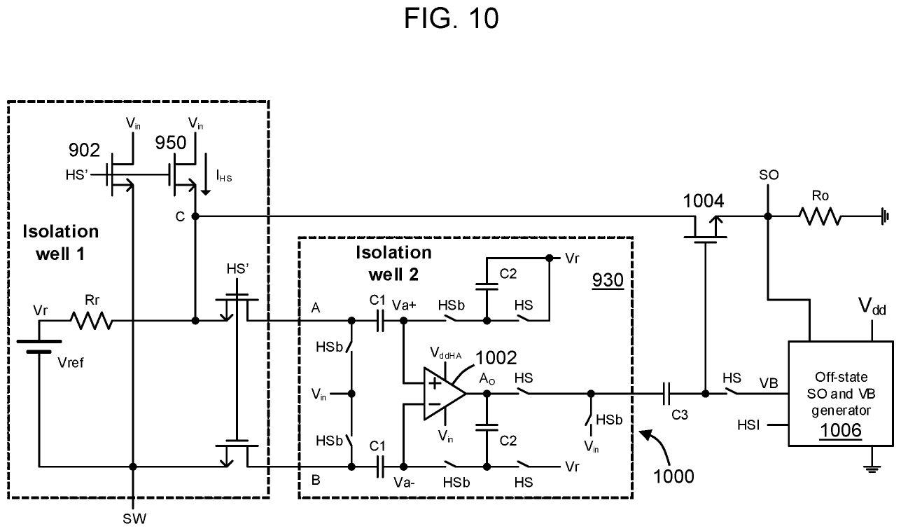

FIG. 9 shows the architecture of an alternative embodiment of the high side current sensing amplifier of the present invention in which a FET 950, rather than a sense resistor, is used to sense the high side current through the high side power FET 902.

The width-length ratio between high side FET 902 and sense FET 950 is assumed to be K:1, where K is a large number (e.g., K=10,000).

If high side power FET 902 and sense FET 950 are matched and their terminal voltages (gate voltages, drain voltages and source voltages) are the same, then the drain current His flowing through high side FET 902 will be K times less than the drain current flow through high side FET 902.

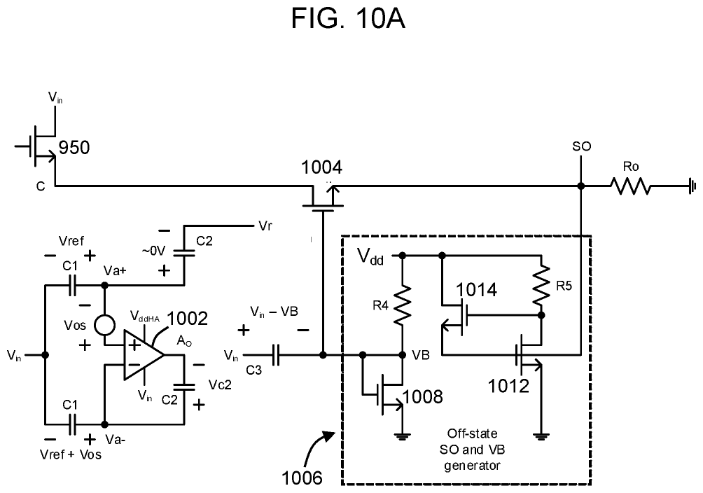

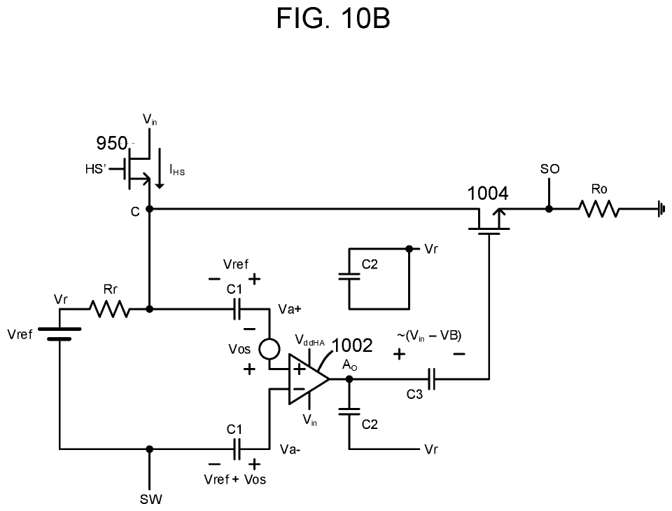

Referring now to FIG. 10, high side current sense amplifier 930 is used: (a) for converting the current flow through high side power FET 902 to a voltage output at SO; and (b) for keeping the source voltage of sense FET 950 the same as the voltage on the SW node when high side FET 902 turns on (with HS' at logic high).

For HS' at logic high, the switches connected to the high side current sense amplifier 930 inputs A and B are turned in current sensing phase (FIG. 10B). For HS' at logic low, the switches connected to A and B are off and the high side current sense amplifier 930 is in reset phase (FIG. 10A).

The Off-state SO and VB generator 1006 is the same as Off-state SO and VB generator 806 shown in FIG. 8A, and functions as described with respect to FIG. 8A.

The switches connected to A and B are shown as two FETs (HSb) controlled by HS′.

HS is reference to Vin and is generated by the Supply & clock generator 940 (in FIG. 9). HSb is the inverted logic signal of HS.

As described in connection with FIG. 8, C3 is introduced for level shifting the op amp output swing to produce a control voltage to the gate of FET 1004 which is close to ground during the current sensing phase.

C3 is required to be a high voltage (greater than Vin) capacitor. As described in connection with FIG. 8, for full integration, C3 can be realized as an integrated GaN FET by connecting the gate and the source terminals of the integrated GaN FET to the gate of FET 1004, with the drain terminal being the other capacitor terminal.

As described in connection with FIG. 7, the reference voltage Vref, together with Rr, is used to provide a non-zero voltage on the current sense amplifier output SO when the high side current I_{HS} is zero with HS' and HS being logic high. As a result, for a negative I_{HS}, SO can still be above ground. Vref is also used to set the input common-mode of the op amp to be approximately Vref with respect to Vin.

Referring now to FIG. 10A, during the reset phase, sensing I_{HS} is not required, and the op amp is reset as described in connection with FIGS. 7A and 8B.

As described previously, Va+ is equal to Vref with respect to Vin in steady stage and Va− will be equal to Vref+Vos w.r.t. Vin. The op amp offset voltage Vos will be stored on the bottom C1.

C3 is charged to a voltage between Vin and VB. Although VB can be set to ground, VB is preferably chosen to be one gate-to-source voltage Vgs above ground as determined by FET 1008 of Off-state SO and VB generator 1006. The advantage of doing this is described in connection with FIG. 8C and also below in connection with FIG. 10B.

FETs 1012, 1014 and R5 in the off-state SO and VB generator will produce a voltage on SO equal to the Vgs of FET 1012 during this phase.

Since SO is equal to the Vgs of FET 1012, and the voltage at the gate of FET 1004 (VB) is equal to the Vgs of FET 1008, the Vgs of FET 1004 will be very small and less than the threshold voltage of FET 1004. Hence, FET 1004 will be off, and SO is determined by Off-state SO and VB generator 1006.

Referring to FIG. 10B, during the current sensing phase, the output of op amp 1002, AO, controls GN through C3. As a result, a feedback loop consisting of op amp 1002, Vref, FET 1004, and Rr is formed. The Off-state SO and VB generator 1006 is turned off and will not affect SO.

Due to the feedback loop, the source voltage of high side FET 950 on node C will be set equal to the source voltage of the power FET (FET 902 in FIGS. 9 and 10), i.e., equal to the voltage at SW. Note that the op amp offset voltage Vos is canceled by the offset voltage stored on the bottom C1. Hence, the adverse effects due to amplification of the op amp offset are minimized. Since all the terminal voltages of FETs 902 and 950 are matched, I_{HS} will be equal to K times less than the drain current flow through FET 902.

I_{HS} together with the current from the voltage reference (equal to Vref/Rr) will flow through FET 1004 to Ro. Hence, the output of high side current sense amplifier 1002, SO, will be equal to I_{HS}×Ro+Vref/Rr×Ro.

As described in connection with FIG. 8C, by setting VB to one Vgs (approximately equal to the gate-to-source voltage of FET 1004) instead of 0V, the swing on SO becomes approximately between Vdd and ground. Hence, setting VB to one Vgs, instead of 0V, allows SO to have a swing of a full supply voltage (i.e., Vdd).

The integrated current sensing amplifier with offset cancellation of the present invention, in its various embodiments described above, has the following features and advantages:

1. Integrating current sense amplifiers with gate drivers and power FETs, as in the present invention, reduces off-chip components. Hence, the integrated current sensing amplifier of the present invention reduces costs and PCB space.

2. In GaN technology, it is difficult to integrate current sense amplifiers due to the lack of GaN PFETs, large VT drift and large VT mismatch. The last two factors result in large amplifier offset voltages which adversely affect the accuracy of the current sensed on the power FETs significantly. To reduce amplifier offsets, the current sensing circuitry of the present invention utilizes the power FET off times for storing offsets on capacitors. The stored offsets are then used for cancelling the amplifier offsets during the power FET on times, which is the interval that requires current sensing.

3. For high-side current sensing, an off-chip PFET may be used to convey the sensing current to a ground referenced resistor. Alternatively and preferably, the present invention provides a high side current sensing amplifier that does not require a PFET, and can therefore be fully implemented in GaN technology.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A current sense amplifier for sensing current flowing through a power FET, comprising:
a current sensing circuit connected across a current sense resistor, the current sensing resistor connected in series with the power FET, wherein the current sensing circuit comprises an op amp with an input offset voltage, a plurality of switches, and a plurality of capacitors;
wherein the current sensing circuit is configured to:
(i) store the input offset voltage of the op amp during a first phase when the power FET is off, and
(ii) sense the current flowing through the power FET during a second phase by measuring the voltage across the resistor when the power FET is on,
wherein the stored input offset voltage of the op amp is used to cancel the input offset voltage of the op amp during the second phase when the power FET is on and the current is sensed.

2. The current sense amplifier of claim 1, wherein the power FET is a low side power FET of a half bridge circuit.

3. The current sense amplifier of claim 1, wherein the power FET is a high side power FET of a half bridge circuit.

4. The current sense amplifier of claim 2, wherein, during the first phase, the current sensing circuit has a first feedback gain and, during the second phase, the current sensing circuit has a second feedback gain, and wherein current sensing circuit comprises a capacitive reset gain circuit for keeping the first feedback gain equal to the second feedback gain.

5. The current sense amplifier of claim 3, further comprising a capacitor connected to the output of the op amp for level shifting the output voltage of the op amp to control the gate voltage of a FET connected to an output of the current sense amplifier, such that the gate voltage of the FET is lower than the input voltage, and the output of the current sense amplifier is referenced to ground.

6. The current sense amplifier of claim 5, implemented in an integrated circuit in GaN technology.

7. The current sense amplifier of claim 6, wherein the FET is a PMOSFET external to the integrated circuit.

8. The current sense amplifier of claim 6, wherein the FET is an enhancement mode GaN FET integrated in the integrated circuit.

9. The current sense amplifier of claim 5, wherein the current sense resistor is implemented by a FET.

10. The current sense amplifier of claim 5, implemented in an integrated circuit in GaN technology, wherein the integrated circuit comprises a supply and clock generator for generating clock signals and supply voltages to the current sense amplifier.

11. The current sense amplifier of claim 8, further comprising circuitry for generating a non-zero current sense output voltage, and for generating a voltage for charging the capacitor, during the first phase when the power FET is off.

12. An integrated circuit comprising a half bridge circuit including a low side power FET, a high side power FET, and the current sense amplifier of claim 1 for sensing the current flowing through the low side FET or the high side FET.

13. The integrated circuit of claim 12, implemented entirely in GaN technology.
